(19) United States
(12) Patent Application Publication
(10) Pub. No.: US 2013/0056790 A1
(43) Pub. Date: Mar. 7, 2013

(54) SEMICONDUCTOR DEVICE AND METHOD FOR MANUFACTURING SAME

(71) Applicant: Keiko KAWAMURA, Kanagawa-ken (JP)

(72) Inventor: Keiko KAWAMURA, Kanagawa-ken (JP)

(73) Assignee: Kabushiki Kaisha Toshiba, Tokyo (JP)

(21) Appl. No.: 13/424,139

(22) Filed: Mar. 19, 2012

(30) Foreign Application Priority Data
Sep. 7, 2011 (JP) 2011-195506

(51) Int. Cl. H01L 29/739; H01L 21/331

(52) U.S. Cl. 257/139; 438/138; 257/E29.198; 257/E21.383

(57) ABSTRACT

According to one embodiment, a semiconductor device includes: a drain layer; a drift layer formed on the drain layer, an effective impurity concentration of the drift layer being lower than an effective impurity concentration of the drain layer; a base layer formed on the drift layer; a source layer selectively formed on the base layer; a gate insulating film formed on inner surfaces of trenches, the trenches piercing the base layer from an upper surface of the source layer; a gate electrode filled into an interior of the trench; an inter-layer insulating film formed on the trench to cover an upper surface of the gate electrode, at least an upper surface of the inter-layer insulating film being positioned higher than the upper surface of the source layer; and a contact mask. The contact mask is formed on the inter-layer insulating film, and is conductive or insulative.

### CROSS-REFERENCE TO RELATED APPLICATIONS

This application is based upon and claims the benefit of priority from the prior Japanese Patent Application No. 2011-195506, filed on Sep. 7, 2011; the entire contents of which are incorporated herein by reference.

### FIELD

Embodiments described herein relate generally to a semiconductor device and a method for manufacturing same.

### BACKGROUND

A power MOS transistor (Power Metal-Oxide-Semiconductor Field-Effect Transistor) is a field effect transistor designed to handle high power. Such a power MOS transistor can be divided into the two structures of a vertical type and a lateral type. The vertical type power MOS transistor can be further divided into the two structures of a planar structure and a trench structure.

In the planar structure, a gate electrode is formed on the upper surface of a semiconductor substrate; and the direction of the current flowing in the channel is the inner-plane direction of the wafer.

On the other hand, in the trench structure, the gate electrode is filled into the interior of a trench made in the semiconductor substrate; and the direction of the current flowing in the channel is the thickness direction of the wafer. In such a case, a source electrode is connected to a source layer through a contact hole made in an insulating film that covers the gate electrode; and a drain electrode is connected to a drain layer that is formed in the back surface of the wafer.

Integration of the transistors in the wafer surface can be higher for the trench structure than for the planar structure. However, because the trenches and the contact holes are made by lithography, higher integration of the semiconductor device is becoming difficult due to the spatial resolution and the error occurring when aligning the masks.

### BRIEF DESCRIPTION OF THE DRAWINGS

FIGS. 1A and 1B are schematic views illustrating the semiconductor device according to a first embodiment, wherein FIG. 1A is a schematic cross-sectional view, and FIG. 1B is a schematic perspective view;

FIGS. 2A and 2B are schematic views illustrating a semiconductor device according to a modification of the first embodiment, wherein FIG. 2A is a schematic cross-sectional view, and FIG. 2B is a schematic perspective view;

FIGS. 3A to 3E are schematic cross-sectional views illustrating a method for manufacturing the semiconductor device according to the first embodiment;

FIGS. 4A and 4B are schematic views illustrating a semiconductor device according to a second embodiment, wherein FIG. 4A is a schematic cross-sectional view, and FIG. 4B is a schematic perspective view;

FIGS. 5A and 5B illustrate a semiconductor device according to a modification of the second embodiment, wherein FIG. 5A is a schematic cross-sectional view, and FIG. 5B is a schematic perspective view; and

FIGS. 6A to 6E are schematic cross-sectional views illustrating a method for manufacturing the semiconductor device according to the first embodiment.

### DETAILED DESCRIPTION

In general, according to one embodiment, a semiconductor device, includes: a drain layer of a first conductivity type; a drift layer of the first conductivity type formed on the drain layer, an effective impurity concentration of the drift layer being lower than an effective impurity concentration of the drain layer; a base layer of a second conductivity type formed on the drift layer; a source layer of the first conductivity type selectively formed on the base layer; a gate insulating film formed on inner surfaces of a plurality of trenches, the plurality of trenches piercing the base layer from an upper surface of the source layer; a gate electrode filled into an interior of the trench; an inter-layer insulating film formed on the trench to cover an upper surface of the gate electrode, at least an upper surface of the inter-layer insulating film being positioned higher than the upper surface of the source layer; and a contact mask formed on the inter-layer insulating film, the contact mask being conductive or insulative.

In general, according to one embodiment, a method for manufacturing a semiconductor device, includes: forming a hard mask on a semiconductor substrate, the semiconductor substrate including a drift layer of a first conductivity type formed on a drain layer of the first conductivity type, an effective impurity concentration of the drift layer being lower than an effective impurity concentration of the drain layer, a plurality of openings extending in one direction being made in the hard mask; making a plurality of trenches extending in the one direction in a portion of the semiconductor substrate higher than an upper surface of the drain layer by performing etching using the hard mask as a mask; forming a gate insulating film on an inner surface of the trench; forming a gate electrode by filling a conductive material into an interior of the trench; forming an inter-layer insulating film on the gate electrode, at least an upper surface of the inter-layer insulating film being higher than an upper surface of the semiconductor substrate and lower than an upper surface of the hard mask; forming a contact mask on the inter-layer insulating film between the hard mask; removing the hard mask by performing etching using the contact mask as a mask; making a contact trench between the trenches from the upper surface of the semiconductor substrate to reach the base layer by performing etching using the contact mask as a mask; forming a base layer of a second conductivity type in a portion of the semiconductor substrate positioned higher than a lower surface of the gate electrode by introducing an impurity using the contact mask as a mask; and forming a source layer of the first conductivity type in a portion of an upper portion of the base layer contacting the trench by introducing an impurity using the contact mask as a mask.

### First Embodiment

Embodiments of the invention will now be described with reference to the drawings.

Although a trench-gate type MOSFET (Metal-Oxide-Semiconductor Field Effect Transistor) is illustrated as a semiconductor device in the embodiments hereinbelow, the semiconductor device may be an IGBT (Insulated Gate Bipolar Transistor). In the case of the IGBT, the n⁺-type drain layer 12 described below may be replaced with a p⁺-type collector layer.

For example, silicon is used as the semiconductor material in the semiconductor devices of the embodiments. Alternatively, a semiconductor other than silicon may be used.

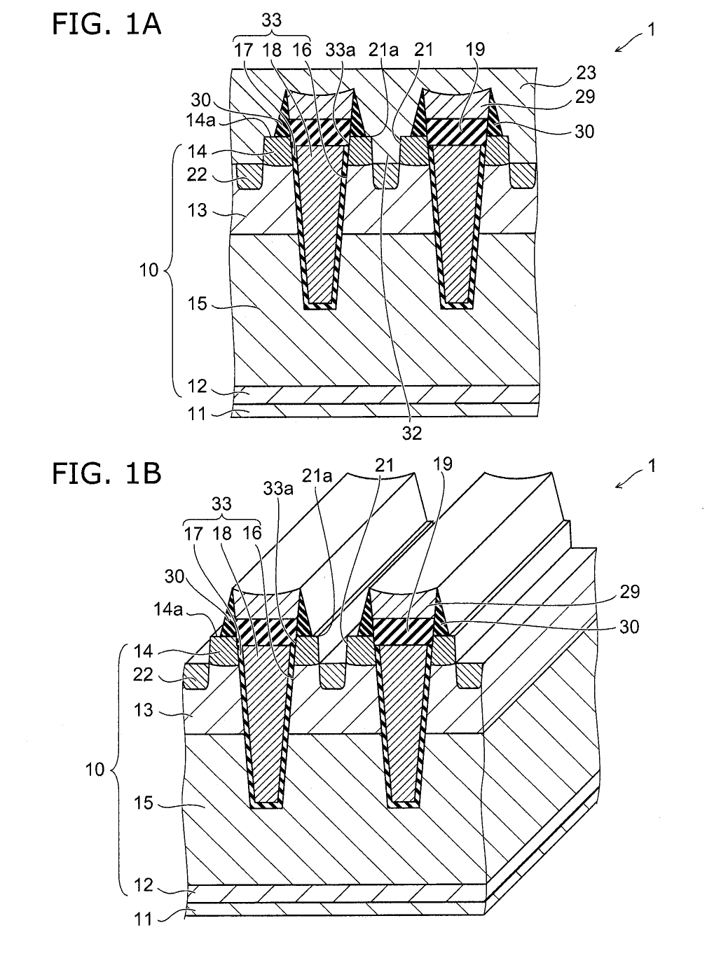

FIGS. 1A and 1B are schematic views illustrating the semiconductor device according to the first embodiment. FIG. 1A is a schematic cross-sectional view; and FIG. 1B is a schematic perspective view.

The semiconductor device 1 of this embodiment includes a substrate layer 10. The substrate layer 10 includes, for example, an n⁺-type drain layer 12, an n⁻-type drift layer 15, a p-type base layer 13, an n⁺-type source region 14, a p⁺-type carrier release layer 22, and a trench gate 33. The effective n-type impurity concentrations of the drain layer 12 and the source region 14 are higher than that of the drift layer 15. The effective p-type impurity concentration of the carrier release layer 22 is higher than that of the base layer 13. In the specification, the concentration of the impurities contributing to the conduction of the semiconductor material is referred to as the effective impurity concentration. For example, in the case where the semiconductor material contains both an impurity that forms donors and an impurity that forms acceptors, the concentration of the activated impurities excluding the cancelled portion of the donors and the acceptors is referred to as the effective impurity concentration.

The semiconductor device 1 further includes a drain electrode 11 electrically connected to the drain layer 12, a source electrode 23 electrically connected to the base layer 13 and the source region 14, and a gate electrode 18 filled into the interior of a trench 16. The source electrode 23 is not illustrated for easier viewing in FIG. 1B.

The drain electrode 11 is provided as a first main electrode on the back surface of the drain layer 12; and the main material of the drain electrode 11 is, for example, a metal. The drain layer 12 and the drain electrode 11 are electrically connected to each other with ohmic contact.

The drift layer 15 is provided on the drain layer 12. For example, phosphorus (P) is introduced to the drift layer 15.

The base layer 13 is provided on the drift layer 15. For example, boron (B) is introduced to the base layer 13.

The multiple trench gates 33 are provided in the base layer 13. The multiple trench gates 33 are made, for example, in a planar pattern having a stripe configuration extending into the page surface. The trench gate 33 includes the trench 16, a gate insulating film 17, and the gate electrode 18.

The trench 16 pierces the base layer 13 to reach the drift layer 15 interior. The gate insulating film 17 is provided on the side wall and the bottom portion of the trench 16. The gate electrode 18 is provided on the inner side of the gate insulating film 17 inside the trench 16. In other words, the gate electrode 18 opposes the base layer 13 with the gate insulating film 17 interposed. Hereinbelow, the trench 16, the gate insulating film 17, and the gate electrode 18 are generally referred to as the trench gate 33.

For example, a silicon oxide film is the main material of the gate insulating film 17. The gate electrode 18 includes a semiconductor (e.g., polycrystalline silicon) having conductivity by an impurity being added. Alternatively, a metal may be used.

An inter-layer insulating film 19 is provided on the gate electrode 18. For example, a silicon oxide film is the main material of the inter-layer insulating film 19. The upper surface of the inter-layer insulating film 19 is formed to be positioned higher than the upper surface of the substrate layer 10.

A contact mask 29 is provided on the upper surface of the inter-layer insulating film 19. For example, silicon oxide or polysilicon into which phosphorus is introduced may be the main material of the contact mask 29.

The source region 14 is provided in a region of the front surface of the substrate layer 10 adjacent to a trench gate opening 33a of the trench gate 33. A front surface 14a of the source region 14 does not contact the contact mask 29 that covers the upper surface of the trench gate 33. The source region 14 has a pn junction with the base layer 13.

A trench contact 32 is formed between the trench gate 33 from the front surface of the substrate layer 10 in the perpendicular direction.

In other words, the source region 14 is formed between the trench gate 33 and the trench contact 32; one side surface of the source region 14 is adjacent to the side surface of the trench gate 33; and one other side surface of the source region 14 is adjacent to the side surface of the trench contact 32.

As illustrated in FIGS. 1A and 1B, a hard mask 30 having silicon oxide as the main material may be adjacently formed from the side surfaces of the inter-layer insulating film 19 and the contact mask 20 over a portion of the front surface 14a of the source region 14.

The trench contact 32 may be shallower or deeper than the trench gate 33 and may or may not reach the drift layer 15. Although the trench contact 32 is shallower than the trench 16 of the trench gate 33 and does not reach the drift layer 15 in the example illustrated in FIGS. 1A and 1B, this is not limited thereto. Although the trench contact 32 is deeper than the bottom portion of the source region 14, the trench contact 32 may be shallower than the source region 14.

Although the trench contact 32 contacts the front surface 14a of the source region 14 at a trench contact opening 21a, the trench contact 32 does not contact the inter-layer insulating film 19 and the contact mask 29.

The source electrode 23 is provided inside a contact trench 21 as a second main electrode. The side surface of the source region 14 has ohmic contact with the source electrode 23 inside the contact trench 21.

The source electrode 23 is provided also on the contact mask 20 and the front surface 14a of the source region 14. The source region 14 is electrically connected to the source electrode 23 by the front surface 14a of the source region 14 also having ohmic contact with the source electrode 23.

The p⁺-type carrier release layer (or contact region) 22 that has a higher p-type impurity concentration than that of the base layer 13 is formed in a region lower than the bottom portion of the contact trench 21.

The carrier release layer 22 has ohmic contact with the source electrode 23 provided inside the contact trench 21. Thereby, the base layer 13 is electrically connected to the source electrode 23 via the carrier release layer 22.

In the semiconductor device 1 according to the embodiment described above, a negative potential is applied to the source electrode 23 of the semiconductor device 1; and a positive potential is applied to the drain electrode 11. The negative potential applied to the source electrode 23 is applied to the source region 14 via the front surface 14a of the source region 14. The negative potential applied to the source electrode 23 also is applied to the carrier release layer 22. On the other hand, the positive potential applied to the drain electrode 11 is applied to the drain layer 12 and the drift layer 15. When the potential of the gate electrode 18 is not more than the threshold in such a case, a depletion layer spreads from the interface between the p-type base layer 13 and the n-type drift layer 15. Therefore, a current does not flow between the drain electrode 11 and the source electrode 23.

When a potential that exceeds the threshold is applied to the gate electrode 18 in a state in which a negative potential is applied to the source electrode 23 and a positive potential is applied to the drain electrode 11, an inversion layer is formed in the portion of the base layer 13 that contacts the gate insulating film 17. An electron current flows through the path of the source electrode 23, the upper surface 14a of the source region, the source region 14, the base layer 13 (the inversion layer), the drift layer 15, the drain layer 12, and the drain electrode 11 by the carriers moving through this inversion layer. Then, the amount of current flowing between the source and the drain is controlled by controlling the gate potential applied to the gate electrode 18.

As described above, the semiconductor device 1 of the embodiment includes the contact mask 29 between the upper surface of the inter-layer insulating film 19 and the source electrode 23. The material of the contact mask 29 may be mainly silicon oxide or polysilicon into which phosphorus is introduced.

In the case where the material of the contact mask 29 is mainly polysilicon into which phosphorus is introduced, a capacitance C_{GS} that occurs between the gate electrode 18 and the contact mask 29 which has the same potential as that of the source electrode film 23 can be optimized by changing the thickness of the inter-layer insulating film 19. For example, the value of the ratio (C_{GD}/C_{GS}) with a capacitance C_{GD} between the gate electrode 18 and the drain electrode film 11 can be reduced by increasing C_{GS}. The value of C_{GS} can be optimized according to whether the semiconductor device 1 is used on the high side, that is, at a location proximal to the power source, or on the low side, that is, at a location proximal to ground.

In the case where the material of the contact mask 29 is silicon oxide, it is possible to further reduce the value of the capacitance C_{GS} between the gate electrode 18 and the source electrode film 23 in the region directly above the gate electrode 18.

Because the inter-layer insulating film 19 is provided to protrude from the upper surface of the base layer 13, the upper end portion of the gate electrode 18 can be disposed proximally to the upper surface of the silicon substrate 10 which is the uppermost portion of the trench 16. Therefore, the source region 14 and the contact trench 21 can be formed to be shallow. As a result, the avalanche breakdown tolerance can be increased.

### Modification

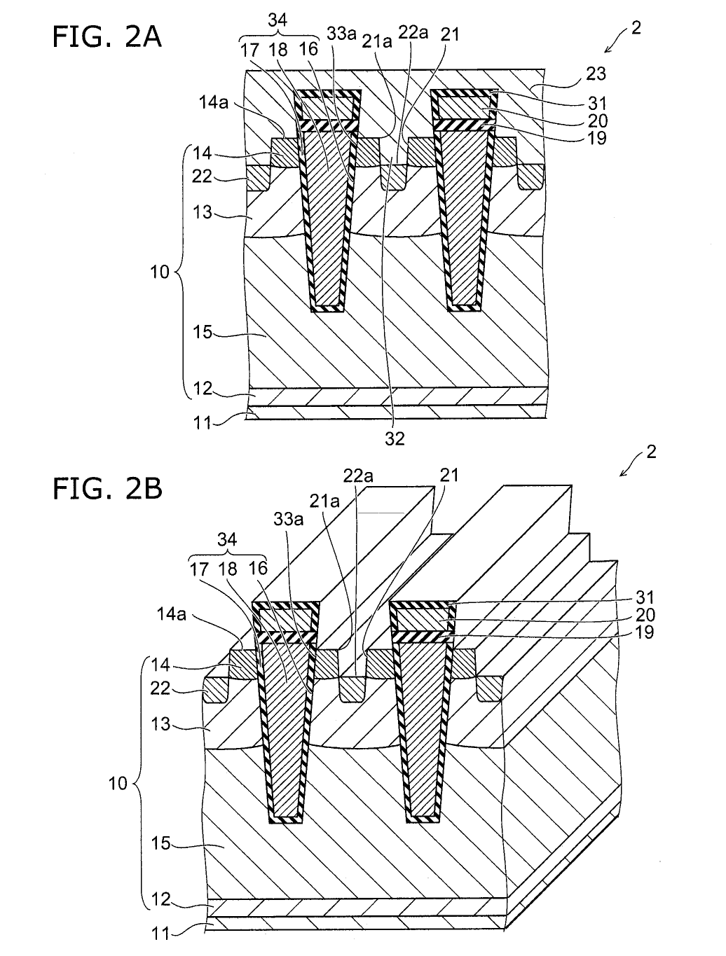

FIGS. 2A and 2B are schematic views illustrating a semiconductor device 2 according to a modification of this embodiment. FIG. 2A is a schematic cross-sectional view; and FIG. 2B is a schematic perspective view.

As illustrated in FIGS. 2A and 2B, the contact mask 20 may be provided in a portion of the center of the upper surface of the inter-layer insulating film 19; and an insulating film 31 that has substantially the same lateral width as the lateral width of the inter-layer insulating film 19 may be provided on the upper surface and the side surface of the contact mask 20. The contact mask 20 is insulated from the source electrode 23 by the insulating film 31.

In the semiconductor device 2 according to the modification of the embodiment illustrated in FIGS. 2A and 2B, the contact mask 20 is in a state of not being electrically connected to anything, i.e., a so-called floating state. The distance between the gate electrode 18 and the source electrode 23 in the region directly above the gate electrode 18 is greater than that of the first embodiment described above. Therefore, it is possible to reduce the value of C_{GS} to be less than the value of C_{GS} of the first embodiment described above.

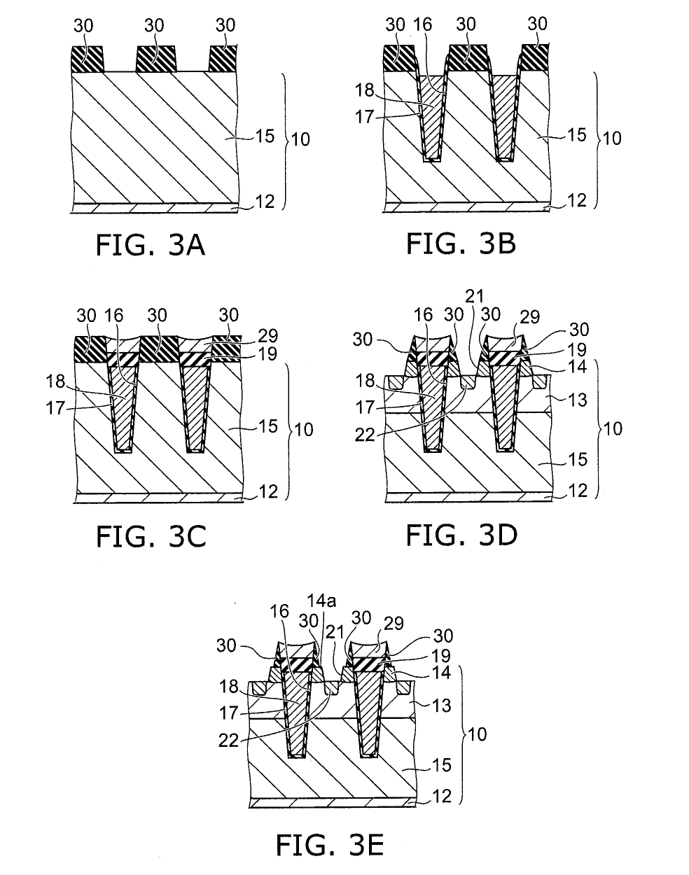

A method for manufacturing the semiconductor device according to the embodiment will now be described with reference to FIGS. 3A to 3E.

As illustrated in FIG. 3A, the drift layer 15 is formed on the substrate (the drain layer) 12. These layers are silicon layers of the n conductivity type. The effective impurity concentration of the drain layer 12 is higher than the effective impurity concentration of the drift layer 15.

Then, the hard mask 30 in which openings are made in multiple trench configurations extending in one direction is provided on the silicon substrate 10. The hard mask 30 is formed by, for example, forming a silicon oxide film on the upper surface of the silicon substrate 10 and subsequently performing selective etching.

Then, as illustrated in FIG. 3B, the trenches 16 are made in the silicon substrate 10. The trenches 16 are made by etching the silicon substrate 10 using the hard mask 30 as a mask.

Continuing, the gate insulating film 17 is formed on the inner surface of the trench 16. The gate insulating film 17 is formed by, for example, oxidizing the inner surface of the trench 16. It is also possible to form a silicon oxide film on the silicon substrate 10 including the inner surface of the trench 16. In such a case, the gate insulating film 17 also is formed on the front surface of the silicon substrate 10 and the side surface of the hard mask 30.

Subsequently, a conductive material, e.g., polysilicon, is deposited on the silicon substrate 10 to fill the interior of the trench 16; and subsequently, the portion of the polysilicon other than the portion disposed in the interior of the trench 16 is removed by etching-back. Thereby, the polysilicon is filled into the interior of the trench 16. The portion of the deposited polysilicon filled into the interior of the trench 16 functions as the gate electrode 18. An impurity, e.g., phosphorus, is introduced to the polysilicon.

Then, as illustrated in FIG. 3C, the inter-layer insulating film 19 is formed on the upper surface of the gate electrode 18. The inter-layer insulating film 19 is formed by, for example, oxidizing the polysilicon of the upper portion of the gate electrode 18 by heat treatment. The inter-layer insulating film 19 also may be formed by depositing a silicon oxide film on the gate electrode 18 to fill between the hard mask 30. The upper surface of the inter-layer insulating film 19 is formed to be positioned higher than the upper surface of the silicon substrate 10. The upper surface of the inter-layer insulating film 19 is formed to be positioned lower than the upper surface of the hard mask 30.

Continuing, the contact mask 29 is formed on the inter-layer insulating film 19. The contact mask 29 is filled into the openings of the hard mask 30 by, for example, depositing polysilicon to fill the openings of the hard mask 30 and cover the hard mask 30 and by subsequently planarizing until the upper surface of the hard mask 30 is exposed. Thereby, the portion of the polysilicon filled into the openings of the hard mask 30 becomes the contact mask 29.

Then, as illustrated in FIG. 3D, the hard mask 30 is removed using the contact mask 29 as a mask. Here, etching may be performed to leave a portion of the hard mask 30 on the side walls of the contact mask 29 and the inter-layer insulating film 19. The hard mask 30 may be caused to remain by, for example, controlling the conditions of the etching to make the trench 16 and the etching-back of the silicon oxide film and the polysilicon to form the gate electrode 18 and the gate insulating film 17. The conditions of the etching are controllable by increasing the time and the component proportion of the etching gas that removes the silicon oxide film.

Then, the base layer 13 is formed by, for example, ion implantation of boron into the silicon substrate 10 between the trenches 16 using the contact mask 29 as a mask. For example, the base layer 13 is formed to the portion of the silicon substrate 10 that contacts the trench 16 by controlling the implantation angle of the ion implantation into the upper surface of the silicon substrate 10 and controlling the heat treatment after the implantation. The base layer 13 is formed to be shallower than a depth corresponding to the lower surface of the gate electrode 18.

Continuing, the source region 14 is formed in a region of the upper layer of the base layer 13 that contacts the trench 16. The source region 14 is formed by ion implantation of phosphorus using the contact mask 29 as a mask. The source region 14 is formed by controlling the implantation angle and the heat treatment described above.

The contact trench 21 is made in the upper surface of the silicon substrate 10 using the contact mask 29 as a mask. The contact trench 21 is made deeply to reach the interior of the base layer 13. Subsequently, the carrier release layer 22 is formed in the region directly under the bottom surface of the contact trench 21. The carrier release layer 22 is formed by ion implantation of boron using the contact mask 20 as a mask. The boron is introduced to the carrier release layer 22 with a concentration higher than the concentration of the boron of the base layer 13.

The contact mask 20 made of polysilicon may be oxidized in a manufacturing process such as activation heat treatment, etc., after the ion implantation to become the contact mask 29 made of silicon oxide. Or, the contact mask 29 made of polysilicon may be deliberately oxidized by performing heat treatment to become the contact mask 29 made of silicon oxide.

Subsequently, as illustrated in FIG. 3E, the side surface of the hard mask 30 is caused to recede. Thereby, the portion 14a of the upper surface of the silicon substrate 10 that contacts the trench 16 is exposed. The etching is performed by, for example, wet etching.

Then, the source electrode 23 made of a metal is formed from above the silicon substrate 10 to cover the contact mask 29, cover the upper surface of the source region 14 exposed between the contact mask 29, and fill the contact trench 21. The source electrode 23 contacts the upper surface 14a of the source layer 14 and an upper surface 22a of the carrier release layer 22 and is electrically connected to the source layer 14 and the carrier release layer 22. The source electrode 23 is an electrode of the source region 14 while functioning as an electrode to discharge the carriers.

In the case where the insulating film 31 is formed on the upper surface and the side surface of the contact mask 29 as in the modification, it is possible to form the insulating film 31 by, for example, causing the upper surface and the side surface of the contact mask 29 made of polysilicon to oxidize by heat treatment. Alternatively, it is also possible to form the insulating film 31 by forming a silicon oxide film on the silicon substrate 10 by CVD and subsequently removing the portion of the silicon oxide film other than the portion on the upper surface and the side surface of the contact mask 29.

The drain electrode film 11 made of a metal is formed on the lower surface of the silicon substrate 10. The drain electrode film 11 contacts the drain layer 12 and is connected to the drain layer 12.

Thus, a semiconductor device 1 such as that illustrated in FIGS. 1A and 1B is manufactured.

According to the method for manufacturing the semiconductor device 1 of the embodiment described above, the contact mask 29 is used as the mask when making the contact trench 21. The inter-layer insulating film can be formed on the gate electrode 18, and the source electrode film 23 can be electrically connected to the source layer 14 without making a contact hole in the inter-layer insulating film. Accordingly, the source electrode film 23 can be formed self-aligningly regardless of the lithography. Thereby, a semiconductor device that does not depend on the spatial resolution of the lithography can be highly integrated.

The upper surface 14a of the source layer 14 may be formed at the upper surface of the silicon substrate 10; and the lower surface of the source electrode 23 may contact the upper surface 14a of the source layer 14. In the case where the source layer 14 is formed by ion implantation or diffusion, the resistance is lowest at the upper surface 14a of the source layer 14. Therefore, the contact resistance between the source electrode film 23 and the source layer 14 can be reduced. Accordingly, it is possible for the semiconductor device to have the same resistance value even in the case where the semiconductor device is integrated.

According to the method for manufacturing the semiconductor device 1 relating to FIGS. 1A and 1B, the contact mask 29 in which the width of the upper surface is wider than the width of the lower surface can be formed by the hard mask 30 having a configuration in which the width of the upper surface is narrower than the width of the lower surface. Therefore, it is possible to change the configuration of the contact mask 29 without increasing the number of processes.

In the case where the contact mask 29 is formed such that the width of the upper surface is wider than the width of the lower surface as illustrated in FIGS. 1A and 1B, the positions of the contact trench 21 and the carrier release layer 22 are not proximal to the trench gate 33. This is because the contact mask 29 is used as the mask when forming the contact trench 21 and the carrier release layer 22. Therefore, the carrier release layer 22 can be formed away from the channel. Therefore, it is possible to uniformly maintain the dopant concentration of the channel.

### Second Embodiment

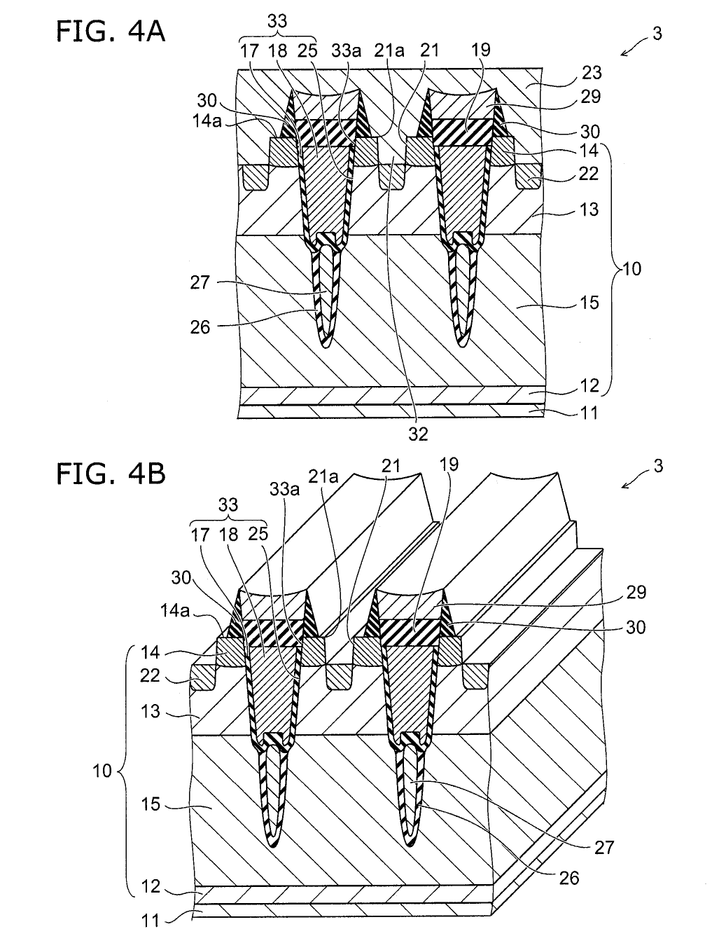

FIGS. 4A and 4B are schematic views illustrating a semiconductor device according to a second embodiment. FIG. 4A is a schematic cross-sectional view; and FIG. 4B is a schematic perspective view.

The semiconductor device 3 of this embodiment includes the substrate layer 10. The substrate layer 10 includes, for example, the n⁺-type drain layer 12, the n⁻-type drift layer 15, the p-type base layer 13, the n′-type source layer 14, the p⁺-type carrier release layer 22, and a trench gate 34. The effective n-type impurity concentrations of the drain layer 12 and the source region 14 are higher than that of the drift layer 15. The effective p-type impurity concentration of the carrier release layer 22 is higher than that of the base layer 13.

The semiconductor device 3 further includes the drain electrode 11 electrically connected to the drain layer 12, the source electrode 23 electrically connected to the base layer 13 and the source region 14, and the gate electrode 18 filled into the interior of the trench 16.

The drain electrode 11 is provided as a first main electrode on the back surface of the drain layer 12; and the main material of the drain electrode 11 is, for example, a metal. The drain layer 12 and the drain electrode 11 are electrically connected to each other with ohmic contact.

The drift layer 15 is provided on the drain layer 12.

The base layer 13 is provided on the drift layer 15.

The multiple trench gates 34 are provided in the base layer 13. The multiple trench gates 34 are made, for example, in a planar pattern having a stripe configuration extending into the page surface. The trench gate 34 includes a trench 25, the gate insulating film 17, and the gate electrode 18.

The trench 25 is made to deeply pierce the base layer 13 to reach the interior of the drift layer 15. A trench bottom portion insulating film 26 is provided on the portion of the inner surface of the trench 25 lower than the upper surface of the drift layer 15, i.e., the portion of the inner surface of the trench 25 that contacts the drift layer 15. The main material of the trench bottom portion insulating film 26 is, for example, a silicon oxide film.

A buried electrode 27 is provided in the portion of the interior of the trench 25 lower than the upper surface of the drift layer 15. The buried electrode 27 is made of a semiconductor (e.g., polycrystalline silicon) having conductivity by an impurity being added.

The same potential as that of the gate electrode 18 is applied to the buried electrode 27; or the same potential as that of the source electrode film 23 is applied to the buried electrode 27.

The gate insulating film 17 is provided on the upper surface of the buried electrode 27 on the inner surface of the trench 25, that is, on the portion of the inner surface of the trench 25 that contacts the base layer 13 and the source layer 14 and on the upper surface of the buried electrode 27. The main material of the gate insulating film 17 is, for example, a silicon oxide film.

The gate electrode 18 is provided on the upper surface of the gate insulating film 17 in the interior of the trench 25. The gate electrode 18 is made of a semiconductor (e.g., polycrystalline silicon) having conductivity by an impurity being added. Alternatively, a metal may be used.

The width of the buried electrode 27 is formed to be finer than the width of the gate electrode 18. The thickness of the trench bottom portion insulating film 26 is formed to be thicker than the thickness of the gate insulating film 17. Otherwise, the configuration is similar to that of the first embodiment described above.

In the semiconductor device 3 according to the embodiment described above, the same potential as that of the gate electrode 18 or the source electrode film 23 is applied to the buried electrode 27. In the case where the same potential as that of the source electrode film 23 is applied to the buried electrode 27, the capacitance C_{GD} between the gate electrode 18 and the drain electrode film 11 is lower than that of the case where the buried electrode 27 is not provided because the source potential is applied to the buried electrode 27 which is disposed at a position between the gate electrode 18 and the drain electrode film 11.

In such a case, the transistor has a field plate structure. Thereby, the resistance of the drift layer 15 can be reduced.

On the other hand, in the case where the same potential as that of the gate electrode 18 is applied to the buried electrode 27, effects similar to those of the field plate described above are obtained even though the value of the potential is different from the value of the potential of the source electrode film 23.

The reason that the resistance of the drift layer 15 can be reduced when using the field plate structure is as follows. In the case where the field plate structure is not used, the breakdown voltage of the transistor decreases when the resistance of the drift layer 15 is reduced. A large space charge occurs in the case where a voltage is applied between the source layer 14 and the drain layer 12 and a depletion layer is formed in the interface between the base layer 13 and the drift layer 15. As the drain voltage is increased further, the gradient of the potential in the interface becomes steep and the electric field becomes greater. The element is destroyed in the case where this electric field exceeds a critical value. Due to such a reason, the breakdown voltage of the transistor decreases when the resistance of the drift layer 15 is reduced.

However, in this embodiment, a large space charge does not occur because the positive charge occurring in the drift layer 15 cancels with the negative charge induced at the front surface of the buried electrode 27. Accordingly, the drift layer 15 can be greatly depleted. Thereby, the resistance of the drift layer can be reduced.

As described above, the semiconductor device 3 of this embodiment includes the contact mask 29 between the upper surface of the inter-layer insulating film 19 and the source electrode 23.

In the case where the material of the contact mask 20 is mainly polysilicon into which phosphorus is introduced, the capacitance C_{GS} that occurs between the gate electrode 18 and the contact mask 29 which has the same potential as that of the source electrode 23 can be optimized by changing the thickness of the inter-layer insulating film 19. For example, the value of the ratio (C_{GD}/C_{GS}) with the capacitance C_{GD} between the gate electrode 18 and the drain electrode film 11 can be reduced by increasing C_{GS}. The value of C_{GS} can be optimized according to whether the semiconductor device 1 is used on the high side, that is, at a location proximal to the power source, or on the low side, that is, at a location proximal to ground.

In the case where the material of the contact mask 29 is silicon oxide, it is possible to further reduce the value of the capacitance C_{GS} between the gate electrode 18 and the source electrode film 23 in the region directly above the gate electrode 18.

Because the inter-layer insulating film 19 is provided to protrude from the upper surface of the base layer 13, the upper end portion of the gate electrode 18 can be disposed proximally to the upper surface of the silicon substrate 10 which is the uppermost portion of the trench 25. Therefore, the source region 14 and the contact trench 21 can be formed to be shallow. As a result, the avalanche breakdown tolerance can be increased.

### Modification

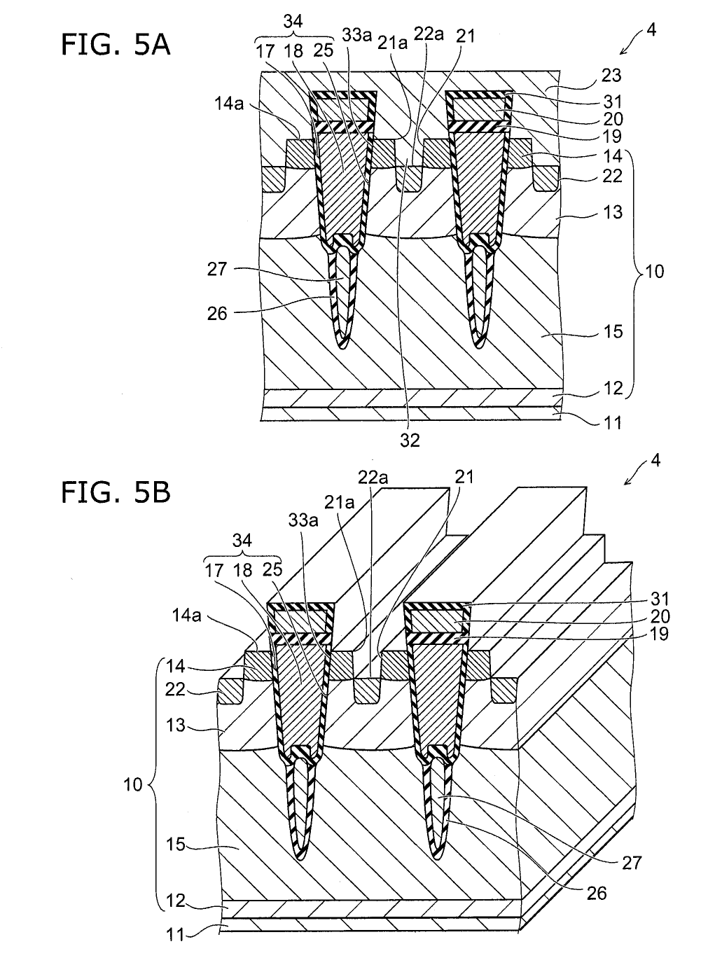

FIGS. 5A and 5B illustrate a semiconductor device 4 according to a modification of this embodiment. FIG. 5A is a schematic cross-sectional view; and FIG. 5B is a schematic perspective view.

As illustrated in FIGS. 5A and 5B, the contact mask 20 may be provided on a portion of the center of the upper surface of the inter-layer insulating film 19; and the insulating film 31 that has substantially the same lateral width as the lateral width of the inter-layer insulating film 19 may be provided on the upper surface and the side surface of the contact mask 20. The contact mask 20 is insulated from the source electrode 23 by the insulating film 31.

In the semiconductor device 4 according to the modification of the embodiment illustrated in FIGS. 5A and 5B, the contact mask 20 is in a state of not being electrically connected to anything, i.e., a so-called floating state. The distance between the gate electrode 18 and the source electrode 23 in the region directly above the gate electrode 18 is greater than that of the second embodiment described above. Therefore, it is possible to reduce the value of C_{GS} to be less than the value of C_{GS} of the second embodiment described above.

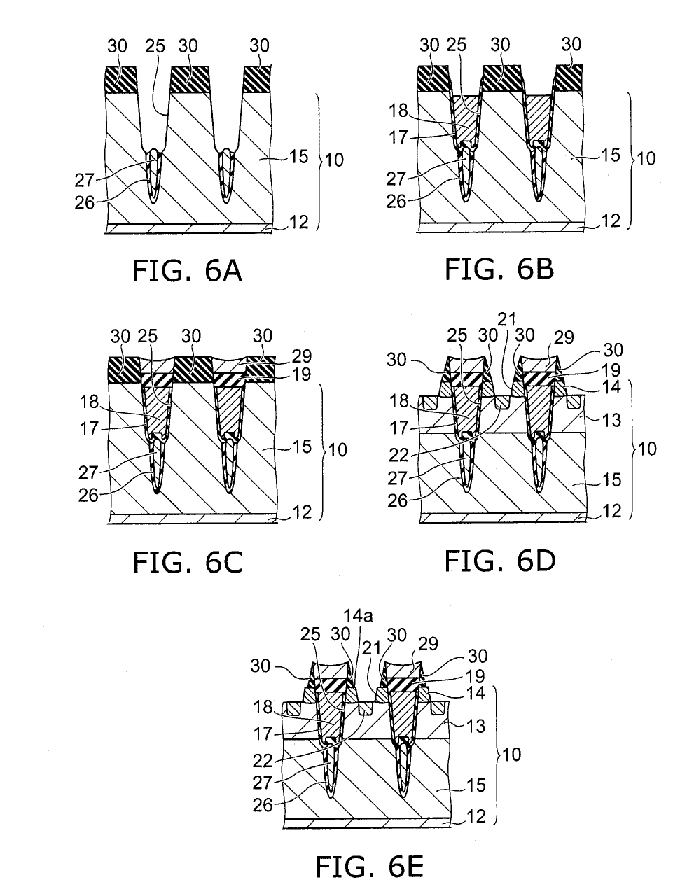

A method for manufacturing the semiconductor device 3 according to the second embodiment will now be described with reference to FIGS. 6A to 6E.

As illustrated in FIG. 6A, the drift layer 15 is formed on the substrate (the drain layer) 12. These layers are silicon layers of the n conductivity type.

Then, the trenches 25 are made in the silicon substrate 10. Normally, the trench 25 has a tapered configuration in which the lower portion is finer than the upper portion.

Continuing, the trench bottom portion insulating film 26 is formed on the inner surface of the trench 25. The trench bottom portion insulating film 26 is formed by, for example, oxidizing the inner surface of the trench 25 by performing heat treatment. The trench bottom portion insulating film 26 also may be formed by forming a silicon oxide film on the silicon substrate 10 including the inner surface of the trench 25 and subsequently removing the portion of the silicon oxide film other than the portion on the inner surface of the trench 25.

Subsequently, a conductive material, e.g., polysilicon, is deposited on the silicon substrate 10 to fill the interior of the trench 25; and subsequently, the portion of the deposited polysilicon other than the portion filled into the bottom portion of the trench 25 is removed by etching-back. Thereby, the polysilicon is filled into the bottom portion of the trench 25. An impurity, e.g., phosphorus, is introduced to the polysilicon. As a result, the buried electrode 27 made of polysilicon is formed on the bottom portion of the trench 25.

Then, as illustrated in FIG. 6B, the portion of the trench bottom portion insulating film 26 positioned higher than the buried electrode 27 is removed.

Continuing, the gate insulating film 17 is formed on the inner surface of the trench 25 higher than the buried electrode 27 and on the upper surface of the buried electrode. For example, the gate insulating film 17 is formed by forming a silicon oxide film on the inner surface of the trench 25 and on the upper surface of the buried electrode 27 by CVD. In such a case, the gate insulating film 17 also is formed on the upper surface of the silicon substrate 10 and on the side surface of the hard mask 30. Other methods of forming the gate insulating film 17 include oxidizing the inner surface of the trench 25 and the upper surface of the buried electrode 27 by performing heat treatment. The film thickness of the gate insulating film 17 is thinner than the film thickness of the trench bottom portion insulating film 26.

Subsequently, a conductive material, e.g., polysilicon, is deposited on the silicon substrate 10 to fill the interior of the trench 25; and subsequently, the portion of the deposited polysilicon other than the portion filled into the interior of the trench 25 is removed by etching-back. Thereby, the polysilicon is filled into the upper portion inside the trench 25. An impurity, e.g., phosphorus, is introduced to the polysilicon. As a result, the gate electrode 18 made of polysilicon is formed in the upper portion inside the trench 25. As described above, the trench 25 has a tapered configuration in which the lower portion is finer than the upper portion; and the width of the gate electrode 18 is wider than the width of the buried electrode 27 by forming the gate insulating film 17 to be thinner than the trench bottom portion insulating film 26.

Then, as illustrated in FIG. 6C, the inter-layer insulating film 19 is formed on the upper surface of the gate electrode 18. The inter-layer insulating film 19 is formed by heat treatment or CVD similarly to the first embodiment described above.

Continuing, the contact mask 29 is formed on the inter-layer insulating film 19. The contact mask 29 is formed by, for example, depositing polysilicon on the silicon substrate 10 to fill the openings of the hard mask 30 and subsequently removing the portion of the polysilicon other than the portion between the hard mask 30 by etching-back.

Then, as illustrated in FIG. 6D, the hard mask 30 is removed using the contact mask 29 as a mask.

Here, etching may be performed to leave a portion of the hard mask 30 on the side walls of the contact mask 29 and the inter-layer insulating film 19. For example, a method similar to that of the first embodiment described above is performed.

Then, the base layer 13 is formed by ion implantation of boron into the silicon substrate 10 between the trenches 25 using the contact mask 29 as a mask. The base layer 13 is formed to the portion of the silicon substrate 10 that contacts the trench 25. The base layer 13 is formed to be shallower than a depth corresponding to the lower surface of the gate electrode 18.

Continuing, the source layer 14 is formed in a region of the upper layer of the base layer 13 that contacts the trench 25. The source layer 14 is formed by ion implantation of phosphorus using the contact mask 29 as a mask.

The contact trench 21 is made in the upper surface of the silicon substrate 10 using the contact mask 29 as a mask. Then, the carrier release layer 22 is formed in the region directly under the bottom surface of the contact trench 21.

Similarly to the first embodiment described above, the contact mask 29 made of polysilicon may be oxidized in a manufacturing process such as activation heat treatment, etc., after the ion implantation to become the contact mask 29 made of silicon oxide. Or, the contact mask 29 made of polysilicon may be deliberately oxidized by performing heat treatment to become the contact mask 29 made of silicon oxide.

As in the modification, in the case where the insulating film 31 is formed on the upper surface and the side surface of the contact mask 20, it is possible to form the insulating film 31 by, for example, causing the upper surface and the side surface of the contact mask 20 made of polysilicon to oxidize by heat treatment. Alternatively, it is also possible to form a silicon oxide film on the silicon substrate 10 by CVD and subsequently remove the portion of the silicon oxide film other than the portion on the upper surface and the side surface of the contact mask 20.

Then, as illustrated in FIG. 6E, a semiconductor device 3 such as that illustrated in FIGS. 4A and 4B is manufactured by performing a process similar to that of FIG. 3E of the first embodiment described above.

According to the semiconductor device 3 and the method for manufacturing the semiconductor device 3 according to this embodiment described above, a lower resistance between the source and the drain can be realized by obtaining a lower resistance of the drift layer 15. The breakdown voltage between the source and the drain also increases. Therefore, the semiconductor device can be highly integrated because downsizing can be performed while realizing a resistance and a breakdown voltage equivalent to those of the case where the buried electrode 27 is not provided.

Also, the semiconductor device 3 including the buried electrode 27 can be manufactured self-aligningly.

In this embodiment, if the trench bottom portion insulating film 26 is formed by heat treatment, the trench bottom portion insulating film 26 can be formed even in the case where the width of the trench 25 is downscaled.

Therefore, the semiconductor device can be highly integrated.

According to the embodiments described above, a semiconductor device and a method for manufacturing the semiconductor device can be provided to realize higher integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a drain layer of a first conductivity type;
a drift layer of the first conductivity type formed on the drain layer, an effective impurity concentration of the drift layer being lower than an effective impurity concentration of the drain layer;
a base layer of a second conductivity type formed on the drift layer;
a source layer of the first conductivity type selectively formed on the base layer;
a gate insulating film formed on inner surfaces of a plurality of trenches, the plurality of trenches piercing the base layer from an upper surface of the source layer;
a gate electrode filled into an interior of the trench;
an inter-layer insulating film formed on the trench to cover an upper surface of the gate electrode, at least an upper surface of the inter-layer insulating film being positioned higher than the upper surface of the source layer; and
a contact mask formed on the inter-layer insulating film, the contact mask being conductive or insulative.

2. The device according to claim 1, comprising a source electrode covering the contact mask and contacting the source layer.

3. The device according to claim 1, further comprising:
a buried electrode provided inside the trench to be lower than the gate electrode and the gate insulating film; and
a trench bottom portion insulating film formed between the buried electrode and the drift layer.

4. The device according to claim 2, wherein:
a contact trench is made in a region of an upper surface of the base layer between the trenches to reach an interior of the base layer; and
the source electrode is filled into the contact trench.

5. The device according to claim 1, wherein:
the drain layer, the drift layer, the base layer, and the source layer are formed of silicon; and
the contact mask includes silicon oxide.

6. The device according to claim 1, wherein:
the drain layer, the drift layer, the base layer, and the source layer are formed of silicon; and
the contact mask includes silicon.

7. The device according to claim 5, further comprising:
a source electrode covering the contact mask and contacting the source layer; and
an insulating film provided between the contact mask and the source electrode.

8. The device according to claim 1, further comprising a hard mask provided on the source layer to be adjacent to a side surface of the inter-layer insulating film and a side surface of the contact mask.

9. The device according to claim 4, further comprising a carrier release layer provided in a region lower than a bottom portion of the contact trench, an impurity concentration of the second conductivity type of the carrier release layer being higher than an impurity concentration of the second conductivity type of the base layer.

10. The device according to claim 1, wherein a material of the contact mask is polysilicon with phosphorus introduced to the polysilicon.

11. The device according to claim 1, wherein a state of the contact mask is floating.

12. The device according to claim 8, wherein the upper surface of the inter-layer insulating film is positioned lower than an upper surface of the hard mask.

13. A method for manufacturing a semiconductor device, comprising:
forming a hard mask on a semiconductor substrate, the semiconductor substrate including a drift layer of a first conductivity type formed on a drain layer of the first conductivity type, an effective impurity concentration of the drift layer being lower than an effective impurity concentration of the drain layer, a plurality of openings extending in one direction being made in the hard mask;
making a plurality of trenches extending in the one direction in a portion of the semiconductor substrate higher than an upper surface of the drain layer by performing etching using the hard mask as a mask;
forming a gate insulating film on an inner surface of the trench;
forming a gate electrode by filling a conductive material into an interior of the trench;
forming an inter-layer insulating film on the gate electrode, at least an upper surface of the inter-layer insulating film being higher than an upper surface of the semiconductor substrate and lower than an upper surface of the hard mask;
forming a contact mask on the inter-layer insulating film between the hard mask;
removing the hard mask by performing etching using the contact mask as a mask;
making a contact trench between the trenches from the upper surface of the semiconductor substrate to reach the base layer by performing etching using the contact mask as a mask;
forming a base layer of a second conductivity type in a portion of the semiconductor substrate positioned higher than a lower surface of the gate electrode by introducing an impurity using the contact mask as a mask; and
forming a source layer of the first conductivity type in a portion of an upper portion of the base layer contacting the trench by introducing an impurity using the contact mask as a mask.

14. The method according to claim 13, further comprising:
forming a trench bottom portion insulating film on the inner surface of the trench;
forming a buried electrode by filling a conductive material into a bottom portion of the trench; and
removing a portion of the trench bottom portion insulating film higher than an upper surface of the buried electrode,
the forming of the gate insulating film including forming the gate insulating film on a portion of the inner surface of the trench higher than the buried electrode and on the upper surface of the buried electrode,
the forming of the gate electrode including forming the gate electrode by filling a conductive material onto the buried electrode in the interior of the trench.

15. The method according to claim 13, further comprising exposing an upper surface of the source layer by reducing a width between the openings of the hard mask.

16. The method according to claim 13, comprising forming a source electrode to cover the contact mask, contact the source layer, and fill the contact trench.

17. The method according to claim 13, wherein:
the semiconductor substrate is formed of silicon;
the contact mask includes silicon; and
the method further comprises oxidizing the contact mask.

18. The method according to claim 13, wherein the removing of the hard mask includes leaving a portion of the hard mask on a side surface of the contact mask and a side surface of the inter-layer insulating film.

19. The method according to claim 13, wherein a carrier release layer is formed in a region directly under a bottom surface of the contact trench by performing ion implantation of boron using the contact mask as a mask.

20. The method according to claim 17, wherein an insulating film is formed on an upper surface and a side surface of the contact mask by causing the upper surface and the side surface of the contact mask to oxidize.
